(19) United States
(12) Patent Application Publication
(10) Pub. No.: US 2004/0238871 A1
(43) Pub. Date: Dec. 2, 2004

(54) Semiconductor device

(75) Inventors: Christian Herzum, Pocking (DE); Ulrich Krumbein, Rosenheim (DE); Christian Kuhn, Munich (DE); Hans Taddiken, Munich (DE)

Correspondence Address: Maginot, Moore & Beck, Suite 3000, 111 Monument Circle, Indianapolis, IN, 46204, US

(73) Assignee: Infineon Technologies AG, Munchen (DE)

(21) Appl. No.: 10/798,719

(22) Filed: Mar. 11, 2004

(30) Foreign Application Priority Data
Mar. 11, 2003 (DE) 103 10 554.9-33

(51) Int. Cl. H01L 27/108

(52) U.S. Cl. 257/303

(57) ABSTRACT

A semiconductor device has a substrate and an active area formed within the same includes a first non-planar metallization level which is formed on the substrate and is in contact with an active area. Further, a second planar metallization level is arranged above the substrate spaced apart from the first metallization level and is connected to the first metallization level via a through connection.

### BACKGROUND OF THE INVENTION

1. Field of the Invention

The present invention relates to a semiconductor device, in particular a field effect transistor or another active device having planar and non-planar metallization levels or planar and non-planar portions of metallization levels, respectively.

2. Description of the Related Art LDMOS transistors (LDMOS=lateral diffused metal oxide semiconductor) are used as large-signal amplifiers, which are for example used in base stations or mobile telephones. The LDMOS transistors available on the market may hereby be classified into two types.

The first type includes one or several planar metallization levels connected to source, drain and gate of the field effect transistor via contact holes and vias or through hole conductors, respectively, as they are also used in standard CMOS technologies.

FIG. 1A shows an example for a known implementation of a field effect transistor with one or several planar metallization levels. In FIG. 1A a field effect transistor is shown schematically, which is formed within a substrate 10. Within the substrate 10 a sinker or substrate contact 12, a source area 14 and a drain area 16 is formed. Between the source area 14 and the drain area 16 the channel area 18 is located. Above the channel area 18 the gate 20 is formed, comprising a polysilicon layer 22 spaced apart from the channel area 18 by a thin oxide layer 24. Further, in the areas of the substrate 10 in which no portions are formed, a field oxide layer 26 is formed at the surface of the substrate 10.

In the known example shown in FIG. 1A, two planar metallization levels 28 and 30 are formed, which are formed above the substrate surface 32 spaced apart from each other. The first metallization level 28 includes a first portion 28a and a second portion 28b. The portion 28a of the first metallization level is connected to the sinker 12 via a first contact 34. Via a second contact 36 the first portion 28a of the first planar metallization level 28 is connected to the source area 14. The second portion 28b of the first metallization level 28 is connected to the drain area 16 via a third contact 38.

The second planar metallization level 30 includes a first portion 30a, which in the illustrated example extends substantially in parallel spaced apart from the second portion 28b of the first planar metallization level 28 and is connected to this first portion 28b of the first planar metallization level via a fourth contact 40. As mentioned above, the example illustrated with reference to FIG. 1A describes a standard CMOS version having planar metallizations. For manufacturing a planar conductive trace for the drain area the topology is filled with an oxide and for example planarized by CMP (CMP=chemical mechanical polishing). Subsequently, contact holes are etched to the silicon and filled with molybdenum in order to generate the contacts shown in FIG. 1A. On the thus formed structure then a planar metallization level is disposed. The disadvantage of this arrangement is that a shielding of the gate 20 is not sufficiently effective.

One advantage of the use of planar metallization levels is that on planar metallization levels an electromigration does not or hardly occur. Planar metallization levels and devices setup along with the same therefore comprise an increased current carrying capacity. A further advantage of the use of planar metallization levels is, that a high packing density, for example a high packing density of storage cells may be achieved.

The second type of LDMOS transistors comprises one or several non-planar metallization levels.

FIG. 1B shows a conventional approach in which non-planar metallization levels are connected. In FIG. 1B a field effect transistor is shown, similar to FIG. 1A, wherein here like reference numerals are used for like elements, and wherein a repeated description of the elements already described with reference to FIG. 1A is omitted. In contrast to the conventional approach shown in FIG. 1A, in FIG. 1B no planar metallization levels are used, but non-planar metallization levels which generally adjust to the contour of the surface of the semiconductor device. Also here, two metallization levels are used, i.e. the first non-planar metallization level 42 and the second non-planar metallization level 44. The first non-planar metallization level 42 includes a first portion 42a which extends starting from the field oxide 26 via the sinker 12, the source area 14, the gate 20 and across the drain area 16. The first portion 42a of the first non-planar metallization level 42 is at least partially arranged on the surface of the substrate 10 is thus in contact with the field oxide 26, the sinker 12 and at least one portion of the source area 14. As it may be seen, the first portion 42a extends further around the gate 20, wherein it is arranged spaced apart from the gate 20 by a suitable insulation layer. In FIG. 1B further the distance delta is shown, which is set between the drain area 16 and the end of the first portion 42a.

The first non-planar metallization level 42 further includes a second portion 42b which at least partially contacts the drain area 16.

The second non-planar metallization level 44 includes a first portion 44a which is separated from the remaining layers by a suitable insulation layer and extends in the area of the drain area 16 to the second portion 42b of the first non-planar metallization level and is in contact with the same.

According to the example illustrated in FIG. 1B, the metallization levels are disposed without planarization. The disadvantage of this approach lies in the resulting edges and steps over which the conductive traces of the metallization level run. On the one hand this takes space and on the other hand it affects the electromigration strength. In the drain area the step is located at the end of the finger when the conductive trace 42b is guided out of the active area and needs to be guided to the field oxide area shown on the right in FIG. 1B. This field oxide 26 may not be omitted due to capacity reasons.

At non-planar metallization levels and in particular at current-carrying edges or steps, respectively, of the same, an increased electromigration occurs, whereby the current carrying capacity is limited. One advantage of the use of non-planar metallization levels is that by a mass shield around the gate a substantially better shielding effect may be achieved compared to when only planar metallization levels are used.

### SUMMARY OF THE INVENTION

Based on this prior art it is the object of the present invention to provide an improved semiconductor device comprising an improved method and improved characteristics.

The present invention is a semiconductor device having a substrate, an active area formed within the substrate, a first non-planar metallization level which is formed on the substrate and is in contact with the active area and a second planar metallization level arranged spaced apart from the first metallization level above the substrate and connected to the first metallization level via a through connection.

According to a preferred embodiment, the semiconductor device is a field effect transistor having a gate, a source area and a drain area. Hereby, the first non-planar metallization level is formed in the form of a first portion connected to the source area and in the form of a second portion connected to the drain area. Further, a third portion is provided, which at least partially covers the gate. The second planar metallization level includes a portion connected to the first portion of the first non-planar metallization level or to the second portion of the first non-planar metallization level.

According to a further preferred embodiment, the first portion and the third portion may be connected to the first non-planar metallization level.

Preferably, between the first non-planar metallization level and the second planar metallization level an insulating layer is arranged, comprising at least one through connection for a connection of the two metallization levels.

More preferably, the third portion of the first non-planar metallization level is implemented in order to shield the gate against electrostatic or electrodynamic interference.

According to a special aspect of the present invention, further an amplifier circuit having an inventive field effect transistor is provided.

According to the invention, the advantages of the above-described conventional approaches are combined, so that according to the invention by the introduction of the non-planar metallization level the feedback capacitance and thus the amplification of the transistor is substantially improved. From the point of view of a non-planar metallization, the inventive approach substantially improves the integration capability to complex circuits, for example for linearization circuits. It is further possible to further substantially reduce the parasitic capacities of the pads. Additionally, the current carrying capacity of the conductive traces is increased because electromigration losses at edges are prevented. The subject of the invention is therefore the combination of the non-planar metallization level with planar metallization levels.

### BRIEF DESCRIPTION OF THE DRAWINGS

These and other objects and features of the present invention will become clear from the following description taken in conjunction with the accompanying drawings, in which:

FIG. 1A shows an illustration of a field effect transistor having planar metallization levels according to the prior art;

FIG. 1B shows a schematical illustration of a field effect transistor having non-planar metallization levels according to the prior art;

FIG. 2 shows an illustration of a preferred embodiment of the present invention;

FIG. 3 shows an illustration of a field effect transistor according to a further embodiment of the present invention;

FIG. 4 shows a sectional expanded view of the illustration of FIG. 3; and

FIGS. 5 to 7 show graphs illustrating the improvements of the inventive approach in contrast to conventional approaches.

### DESCRIPTION OF THE PREFERRED EMBODIMENTS

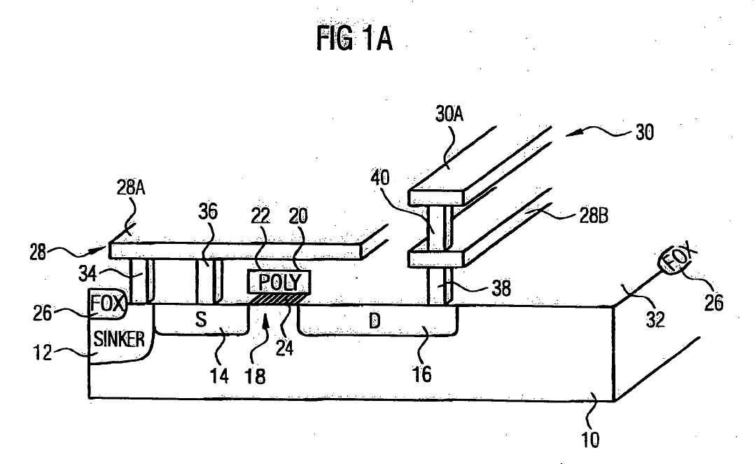

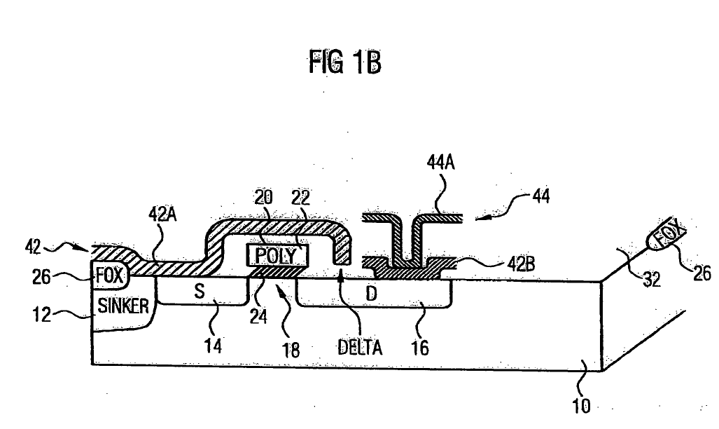

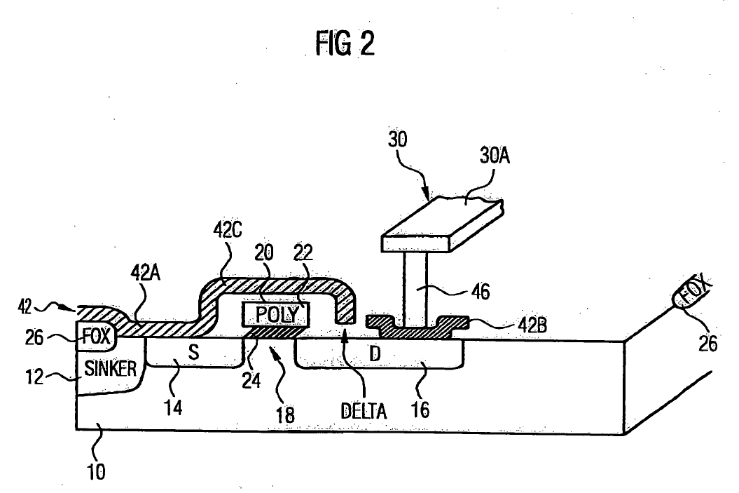

With reference to FIG. 2, in the following a preferred embodiment is described in more detail, wherein in the following explanation of the inventive approach in the figures those elements which were already described with reference to FIGS. 1A and 1B are provided with the same reference numerals.

FIG. 2 shows a field effect transistor structure similar to FIGS. 1A and 1B comprising the sinker or contact terminal 12 within a substrate. Further, within the substrate the source area 14 and the drain area 16 are formed, between which a channel area 18 is defined. Above the channel area 18 the gate structure 20 consisting of the polysilicon gate 22 and the oxide layer 24 is arranged. As it may be seen from FIG. 2, according to the invention the approach according to FIG. 1A (planar metallization levels) is combined with the approach according to FIG. 1B (non-planar metallization levels). The first metallization level is here formed by the non-planar metallization level 42 comprising the three portions 42a, 42b and 42c, wherein in contrast to the prior art now the second metallization level is formed by the planar metallization level 30 which comprises a conductive trace 30a similar to FIG. 1B. The conductive trace 30a is here directly connected to the non-planar portion 42b of the first metallization level 42 via a contact 46.

According to the invention, thus, as it may be seen from FIG. 2, the proceedings described above with reference to FIGS, 1A and 1B are combined. The first metallization level is not planar, whereby a good shielding of the gate is achieved. In the drain area, this metallization level is ended due to the field oxide 26 before possibly setting steps, the conductive trace according to portion 42b is thus not implemented so far that it extends in steps over the field oxide 26 in the right area of FIG. 2. Via vias (plugs between metal levels) the second metallization level is connected. It carries the current out of the finger and is planar.

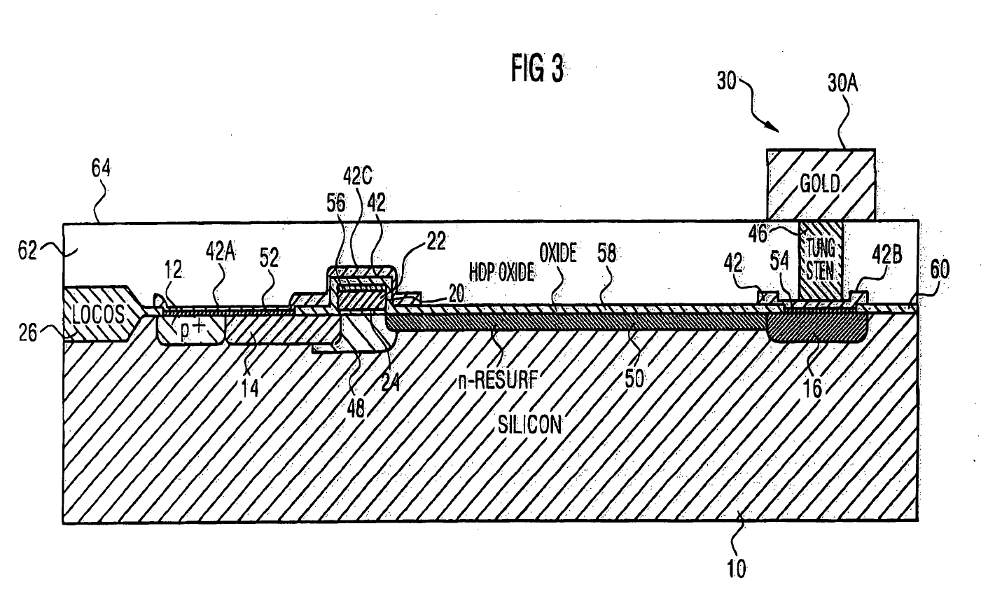

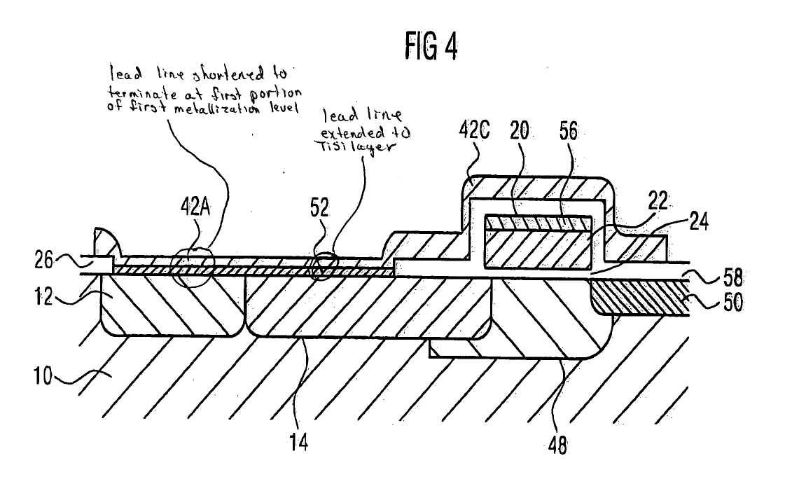

With reference to FIGS. 3 and 4, in the following a detailed illustration of a field effect transistor according to a preferred embodiment of the present invention is explained in more detail, wherein FIG. 4 is an expanded sectional view. Also here, again like reference numerals are used for like elements.

FIGS. 3 and 4 are schematical illustrations of a vertical section through a field effect transistor according to a preferred embodiment of the present invention. At that time, FIG. 4 is an expanded illustration of a section of FIG. 3.

The field effect transistor according to this preferred embodiment includes the substrate 10 (e.g. a p-doped substrate), in which the p+-doped sinker or substrate contact 12, respectively, the n+-doped source or the n+-doped source area 14, respectively, a p-doped body or body area 48, respectively, an n-doped resurf area 50 (resurf=reduced surface field) and the n+-doped drain or the n+-doped drain area 16, respectively, are arranged.

A titanium silicon layer (TiSi layer) 52 is arranged on the surface of the substrate 10 so that it borders on the source 14 and the sinker 12 and at least partially covers the same. As the TiSi layer 52 comprises a high electric conductivity and preferably respectively covers a face as large as possible of the sinker 12 and the source 14, a current flows between the n+-doped source and the p+-doped sinker across the TiSi layer 52 which thus represents a silicide current bridge. A further TiSi layer 54 is arranged on the surface of the substrate 10 so that it borders on the drain 16. The gate 20 is arranged at the surface of the substrate 10 such that it opposes the body area 48 and is only separated from this area by the thin oxide layer 24. The gate 20 is a stack of the polysilicon layer 22 and a further TiSi layer 56 which comprises a lower thickness than the polysilicon layer 22 and is arranged on a side of the polysilicon layer 22 facing away from the substrate 10.

Portions of the surface of the substrate 10 not covered by one of the TiSi layers 52, 54 or by the gate 20 are covered by the LOCOS layer 26 (LOCOS=local oxidation of silicon) or by the oxide layers 58, 60. Thus, the oxide layer 58 covers the gate 20 or all surfaces of the same, respectively, wherein the gate oxide layer 24 is here formed by a part of the oxide layer 58 between the gate 20 and the surface of the substrate 10.

Above the TiSi layers 52, 54, the LOCOS layer 26 and the oxide layers 58, 60 the first non-planar metallization level 42 is formed, including the first portion 42a bordering on the TiSi layer 52 above the source 14 and the sinker 12, the second portion 42b which borders on the same TiSi layer 54 above the drain 16 and electrically contacts the same or is electrically conductively connected to the same, respectively, and the third portion 42c bordering on the first portion 42a and being preferably integrally implemented with the same. The third portion 42c covers the gate 20 at least partially, wherein it is spaced apart from the same by the interpositioned oxide layer 58 and electrically insulated from the same. The portions 42a, 42b and 42c of the non-planar metallization level 42 are preferably generated by first generating an non-structured metal layer planarily over the entire surface of the LOCOS layer 26, the TiSi layers 52, 54 and the oxide layers 58, 60 and then structuring the same laterally by a lift off process or using a photoresist mask and an etching bath. The first metallization level or layer, respectively, is thus basically adjusted to the contour of the substrate surface and is therefore not planar.

The field effect transistor further includes an oxide layer 62 (HDP layer) arranged on the structure as it results after the generation of the first metallization level 42. The surface 64 of the oxide layer 62 facing away from the substrate 10 is planarized. On the planarized surface 64 of the oxide layer 62 the second planar metallization level 30 is formed. In the illustrated embodiment the same includes conductive traces 30a for wiring the field effect transistor and if applicable further active and passive devices.

The conductive trace 30a is electrically conductively connected to the second portion 42b of the first non-planar metallization level 42 and thus to the drain 16 through tungsten plugs 46 in the oxide layer 62. The source 14 may be contacted in the same way as the drain 16, by a tungsten plug extending from a further portion of the second planar metallization level through the oxide layer 62 to the first portion 42a of the first non-planar metallization level 42.

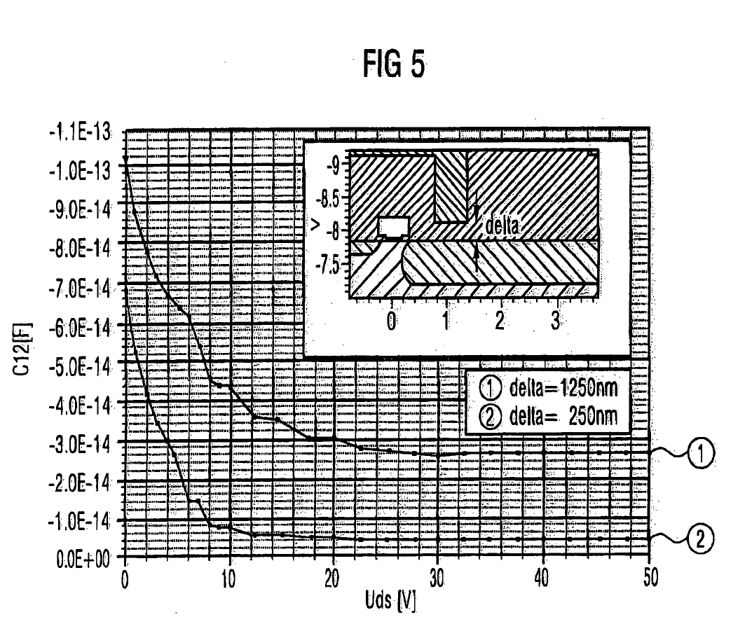

With reference to FIGS. 5 to 7, in the following with reference to the graphs illustrated there, the functionality and the advantages of the inventive arrangement are explained in more detail, among others in connection to a known approach.

In FIG. 5, the feedback capacity C12 is plotted as a function of the drain voltage UDS. The schematical image of a section of the semiconductor structure described with reference to FIG. 2 or FIG. 3, respectively, inserted in FIG. 5, shows the device having a source area on the left side and a drain area on the right side. The third portion 42c is formed as a shield over the gate polysilicon 22 and reaches down on the drain side so that it shows a distance to the underlying area which is referred to as delta similar to FIGS. 1B and 2. Depending on how far the shield reaches down, different feedback capacities result. With a value of delta=1.25 μm (curve 1) the feedback capacity of the cell for drain voltages over 30 V is about 25 fF. In this case, the metallization would not have reached down on the drain side and would correspond to the case of an exclusively planar metallization, as it was described with reference to FIG. 1A. For a value of delta=250 nm (curve 2) the shield 42c reaches down on the drain side as in the image shown in FIG. 5 or similar to FIGS. 2 and 3, wherein here a gate polysilicon thickness of about 300 nm is assumed. As it may be seen, with high separation voltages a feedback capacity C12 of about 4 fF is achieved, and thus due to the inventive implementation a clear reduction of the feedback capacity is achieved.

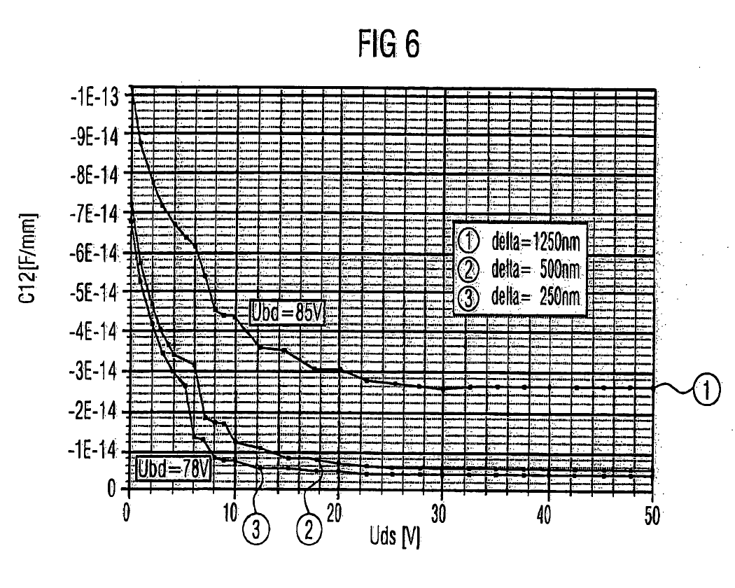

In FIG. 5 again the feedback capacity C12 is plotted versus the drain voltage UDS, wherein here curve 1 illustrated in FIG. 6 corresponds to curve 1 of FIG. 5, and the curve 3 corresponds to curve 2 of FIG. 5. Additionally, a further curve for a value of delta=500 nm (curve 3) was inserted from which it results that also for shield arrangements 42c which do not reach down as far as it was described with reference to FIG. 5, also a clear reduction of a feedback capacity may be achieved compared to a planar metallization approach (see curve 1).

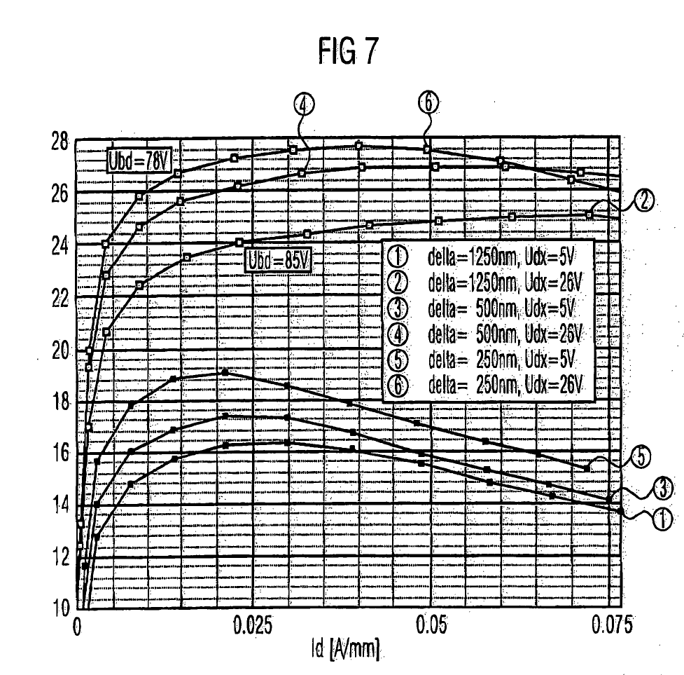

In FIG. 7 the maximum achievable gain with a stable matching (maximum stable gain=MSG) is plotted as the function of the drain current for two drain voltages, 5 V and 26 V. As it may be seen from FIG. 7, the MSG increases with a decreasing delta, wherein by the better shielding the gain is increased by up to 3 dB, which is a substantial increase. In the curves 2 and 6 additionally the drain breakthrough voltage is indicated similar to the curves 1 and 3 in FIG. 6. As it may further be seen, also the drain breakthrough voltage slightly decreases due to the fact that the shield somewhat electrically shortens the resurf path 50 of the LDMOS.

The present invention was illustrated above with reference to an LDMOS field effect transistor having a long resurf area 50. The present invention may, however, also well be applied advantageously to other field effect transistor types. Further, the present invention does not require it to be an n-channel field effect transistor, as illustrated, but may also be well realized with a p-channel field effect transistor. Also the materials of the substrate 10 and thus of the source 14, the drain 16, the sinker 12, the body area 48 and the resurf area as well as of the gate 20 may be easily be replaced by other materials, for example by gallium arsenide (GaAs). Instead of the LOCOS layer 26 and the oxide layers 58, 60, layers of other electrically insulating materials may be used, for example of nitrides Further, instead of the TiSi layers 52, 54, 56 other silicides or other electrically conductive materials may be used which are suitable for contacting doped semiconductor areas. Also the tungsten plug 46 may be replaced by a plug or through hole conductor, respectively, made of another material.

In the preferred embodiment illustrated in FIGS. 1 and 2, the LOCOS layer 26 preferably comprises a thickness of 330 nm. The oxide layer 26 is preferably an HDP oxide (HDP=high density plasma) with a thickness of 2.5 μm to 3 μm. The laterally structured metal layer preferably comprises titanium Ti or titanium nitride TiN or aluminum. Titanium and titanium nitride comprise a higher specific resistance, may, however, be applied without a barrier onto a silicon surface. Aluminum comprises a lower specific resistance, a barrier layer is to be provided, however, between aluminum and a silicon surface.

Although the present invention was explained in more detail above with reference to a preferred embodiment including a field effect transistor, it is obvious that the inventive approach may also be used for other devices with active areas using two metallization levels, of which one is planarized and the other is non planarized, like for example other field effect transistor structures, bipolar transistor structures, diode structures etc.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A semiconductor device, comprising a substrate;
an active area formed within the substrate;
a first non-planar metallization level which is formed on the substrate and is in contact with the active area; and
a second planar metallization level arranged spaced apart from the first metallization level above the substrate and connected to the first metallization level via a through connection.

2. The semiconductor device according to claim 1, wherein the semiconductor device includes a field effect transistor having a gate, a source area and a drain area, wherein the first non-planar metallization level includes a first portion connected to the source area, a second portion connected to the drain area and a third portion at least partially covering the gate, and wherein the second planar metallization level includes at least one portion connected to the second portion of the first non-planar metallization level.

3. The semiconductor device according to claim 2, wherein the first portion and the third portion of the first non-planar metallization level are connected.

4. The semiconductor device according to claim 2, wherein between the first non-planar metallization level and the second planar metallization level an insulating layer is arranged, wherein in the insulating layer at least one through connection for a connection of the first non-planar metallization level to the second planar metallization level is formed.

5. The semiconductor device according to claim 2, wherein the third portion is implemented to shield the gate against electrostatic or electrodynamic interferences.

6. An amplifier circuit comprising a field effect transistor comprising:
a substrate;
an active area formed within the substrate comprising a gate, a source area and a drain area;
a first non-planar metallization level which is formed on the substrate and is in contact with the active area; and
a second planar metallization level arranged spaced apart from the first metallization level above the substrate and connected to the first metallization level via a through connection; and,
wherein the first non-planar metallization level includes a first portion connected to the source area, a second portion connected to the drain area and a third portion at least partially covering the gate, and wherein the second planar metallization level includes at least one portion connected to the second portion of the first non-planar metallization level.

7. The amplifier circuit of claim 6, wherein the first portion and the third portion of the first non-planar metallization level are connected.

8. The amplifier circuit of claim 6, wherein between the first non-planar metallization level and the second planar metallization level an insulating layer is arranged, wherein in the insulating layer at least one through connection for a connection of the first non-planar metallization level to the second planar metallization level is formed.

9. The amplifier circuit of claim 6, wherein the third portion is implemented to shield the gate against electrostatic or electrodynamic interferences.

10. The semiconductor device according to claim 1, wherein the semiconductor device includes a field effect transistor having a gate, a source area and a drain area, wherein the first non-planar metallization level includes a first portion connected to the source area, a second portion connected to the drain area and a third portion at least partially covering the gate, and wherein the second planar metallization level includes at least one portion connected to the first portion of the first non-planar metallization level.

11. The semiconductor device according to claim 10, wherein the first portion and the third portion of the first non-planar metallization level are connected.

12. The semiconductor device according to claim 10, wherein between the first non-planar metallization level and the second planar metallization level an insulating layer is arranged, wherein in the insulating layer at least one through connection for a connection of the first non-planar metallization level to the second planar metallization level is formed.

13. The semiconductor device according to claim 10, wherein the third portion is implemented to shield the gate against electrostatic or electrodynamic interferences.

14. A semiconductor device comprising:
a substrate;
active areas formed within the substrate comprising a source area and a drain area;
a gate disposed between the source area and the drain area and insulated from the substrate by an oxide layer;
a first non-planar metallization level formed on the substrate in contact with the active areas including a first portion connected to the source area, a second portion connected to the drain area and a third portion at least partially covering the gate, the third portion including a portion extending downwardly between the gate and the second portion and terminating at an end displaced from the substrate by a displacement; and
a second planar metallization level arranged spaced apart from the first metallization level above the substrate and connected to the second portion of the first metallization level via a through connection.

15. The semiconductor device of claim 14, wherein the first portion and the third portion of the first non-planar metallization level are connected.

16. The semiconductor device of claim 14, wherein between the first non-planar metallization level and the second planar metallization level an insulating layer is arranged, wherein in the insulating layer at least one through connection for a connection of the first non-planar metallization level to the second planar metallization level is formed.

17. The semiconductor device of claim 15, wherein the third portion is implemented to shield the gate against electrostatic or electrodynamic interferences.

18. The semiconductor device of claim 15, wherein the third portion is spaced apart from the second portion and the displacement is less than about 500 nm.

19. The semiconductor device of claim 18, and further comprising an oxide layer disposed between the third portion and the gate.

20. The semiconductor device of claim 19, and further comprising a reduced surface field area formed in the substrate and disposed between the gate and the drain area.
